(19) United States
(12) Patent Application Publication
(10) Pub. No.: US 2026/0309794 A1
(43) Pub. Date: Oct. 8, 2026

(54) Voltage Monitoring Device

(71) Applicant: Caterpillar Inc., Peoria, IL (US)

(72) Inventors: Gopalakrishnan Kanniappan, Tiruvannamalai (IN); Aswak Shanavaz, Tiruppur (IN); Sudarshan Varadharajan, Bangalore (IN); Chandana Ramkumar, Coimbatore (IN); Gowtham Kumar, Puducherry (IN)

(21) Appl. No.: 19/482,603

(22) PCT Filed: Apr. 18, 2024
(86) PCT No.: PCT/US2024/025075

§ 371 Date: Nov. 7, 2025

(30) Foreign Application Priority Data
May 17, 2023 (IN) 202311034433

(51) Int. Cl. G01R 31/3835; G01R 1/02; G01R 19/165; G01R 31/371; H02J 7/96

(52) U.S. Cl. CPC G01R 31/3835; G01R 1/025; G01R 19/16542; G01R 31/371; H02J 7/96

(57) ABSTRACT

A voltage monitoring device for monitoring voltages of more than one battery, wherein the voltage monitoring device comprises a voltage sensor configured to measure a voltage value of a battery. The voltage sensor is connected to one battery at a given time. The voltage monitoring device is configured to connect to terminals of more than one battery. Each battery is electrically connected to a voltage sensor and a voltage value of the battery connected to the voltage sensor is measured, wherein during the measurement the battery being measured is electrically connected only to the voltage monitoring device. The voltage value of each battery is recorded against a battery identifier and a time stamp. The recorded voltage values are output. In an event that a recorded voltage value is below a threshold voltage, a low voltage notification is not provided.

### FIELD OF THE DISCLOSURE

The disclosure relates to the field of batteries.

### BACKGROUND

It is known to store batteries in an idle or disconnected state, wherein the batteries are not connected to loads. During storage, it is possible that batteries can undergo a drop in voltage. A drop in voltage of a battery in storage can be indicative of changes to the health of the battery.

Manually checking and recording a voltage of each individual battery is a time-consuming task, that is prone to errors. Conventionally, voltages of batteries are automatically monitored only when the batteries are connected to loads. For example, U.S. Pat. No. 11,300,624B2 discusses monitoring the voltages of batteries that are connected in a circuit. For example, the batteries are connected to a power grid or to a drive system providing motive power to various vehicles.

### SUMMARY

Against this background, according to a first aspect of the disclosure there is provided a voltage monitoring device for monitoring voltages of more than one battery, wherein the voltage monitoring device comprises a voltage sensor configured to measure a voltage value of a battery; and a multiplexer configured to sequentially electrically connect the voltage sensor to the more than one battery, such that the voltage sensor is connected to one battery at a given time. The voltage monitoring device is configured to connect to terminals of more than one battery. The voltage monitoring device is further configured to sequentially electrically connect each battery to the voltage sensor using the multiplexer and measure a voltage value of the battery connected to the voltage sensor, wherein during the measurement the battery being measured is electrically connected only to the voltage monitoring device. The voltage monitoring device is further configured to record the voltage value of each battery against a battery identifier and a time stamp. The voltage monitoring device is further configured to output the recorded voltage values, wherein outputting the recorded voltage values comprises displaying the recorded voltage values on a display. In an event that a recorded voltage value is below a threshold voltage, the voltage monitoring device is further configured to provide a low voltage notification.

In this way, the voltage of each battery may be monitored while the battery is in storage without need for an operator to manually measure the voltages individually. The voltages of the batteries may be monitored while the batteries are not connected to any load or any electrical circuit other than the voltage monitoring device. The voltages may be monitored automatically, and a notification provided in an event that a voltage is below a threshold value. An operator receiving a low voltage notification may charge the battery having the low voltage, replace the battery having the low voltage or otherwise maintain the voltage having the low voltage. The use of the multiplexer allows the automatic monitoring of more than one battery using only one voltage sensor.

According to a second aspect of the disclosure a method is provided of monitoring voltages of more than one battery using a voltage monitoring device. The voltage monitoring device comprises a voltage sensor configured to measure a voltage value of a battery; and
a multiplexer configured to sequentially electrically connect the voltage sensor to the more than one battery, such that the voltage sensor is connected to one battery at a given time. The method comprises:
a. connecting the voltage monitoring device to terminals of more than one battery;
b sequentially electrically connecting each battery to the voltage sensor using the multiplexer and measuring a voltage value of the battery connected to the voltage sensor, wherein during the measurement the battery being measured is electrically connected only to the voltage monitoring device;
c. recording the voltage value of each battery against a battery identifier and a time stamp;
d. outputting the recorded voltage values, wherein outputting the recorded voltage values comprises displaying the recorded voltage values on a display; and
e. in an event that a recorded voltage value is below a threshold voltage, providing a low voltage notification.

According to a third aspect of the disclosure, a voltage monitoring device for monitoring voltages of more than one battery is provided. The voltage monitoring device comprises:
more than one voltage sensor, wherein each voltage sensor is configured to measure a voltage value of a battery; and a housing configured to contain the more than one voltage sensor. The voltage monitoring device is configured to connect a voltage sensor to terminals of each battery, such that each voltage sensor is connected to a battery. The voltage monitoring device is further configured to measure a voltage value of each battery connected to a voltage sensor, wherein during the measurement the battery being measured is electrically connected only to the corresponding voltage sensor. The voltage monitoring device is further configured to record the voltage value of each battery against a battery identifier and a time stamp. The voltage monitoring device is further configured to output the recorded voltage values, wherein outputting the recorded voltage values comprises displaying the recorded voltage values on a display. In an event that a recorded voltage value is below a threshold voltage, the voltage monitoring device is further configured to provide a low voltage notification.

In this way, the voltage of each battery may be monitored while the battery is in storage. The voltages of the batteries may be monitored while the batteries are not connected to any load or any electrical circuit other than the voltage monitoring device. The voltages may be monitored automatically, and a notification provided in an event that a voltage is below a threshold value. An operator receiving a low voltage notification may charge the battery having the low voltage, replace the battery having the low voltage or otherwise maintain the voltage having the low voltage. The housing allows a convenient and efficient way to operate more than one voltage sensor, and output the measured values.

According to a fourth aspect of the disclosure, a method is provided of monitoring voltages of more than one battery using a voltage monitoring device. The voltage monitoring device comprises more than one voltage sensor, wherein each voltage sensor is configured to measure a voltage value of a battery; and a housing configured to contain the more than one voltage sensor. The method comprises:
a. connecting a voltage sensor to terminals of each battery, such that each voltage sensor is connected to a battery;
b measuring a voltage value of each battery connected to a voltage sensor, wherein during the measurement the battery being measured is electrically connected only to the corresponding voltage sensor;
c. recording the voltage value of each battery against a battery identifier and a time stamp;
d. outputting the recorded voltage values, wherein outputting the recorded voltage values comprises displaying the recorded voltage values on a display; and
e. in an event that a recorded voltage value is below a threshold voltage, providing a low voltage notification.

### BRIEF DESCRIPTION OF THE DRAWINGS

A specific embodiment of the disclosure will now be described, by way of example only, with reference to the accompanying drawings in which:

FIG. 1 shows a schematic diagram illustrating five batteries connected to a voltage monitoring device according to an embodiment of the present disclosure.

FIG. 2 shows a schematic diagram illustrating a rack holding batteries connected to a voltage monitoring device according to an embodiment of the present disclosure.

FIG. 3 shows a flowchart illustrating a method of monitoring voltages according to an embodiment of the present disclosure.

FIG. 4 shows a flowchart illustrating a method of monitoring voltages according to an embodiment of the present disclosure.

FIG. 5 shows a schematic diagram illustrating five batteries each connected to a voltage sensor of a voltage monitoring device according to an embodiment of the present disclosure.

FIG. 6 shows a schematic diagram illustrating a rack holding batteries wherein each battery is connected to a voltage sensor of a voltage monitoring device according to an embodiment of the present disclosure.

FIG. 7 shows a flowchart illustrating a method of monitoring voltages according to an embodiment of the present disclosure.

### DETAILED DESCRIPTION

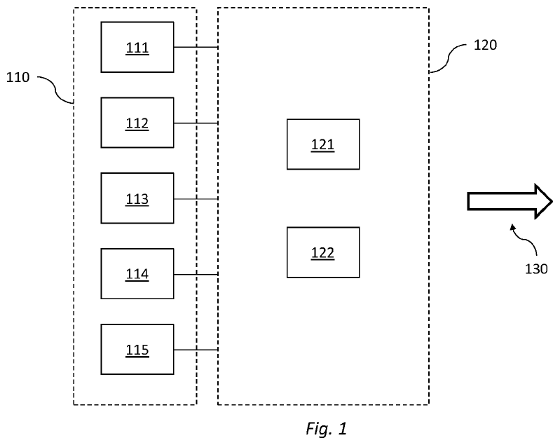

A voltage monitoring device is provided for monitoring voltages of more than one battery. With reference to FIG. 1, a block diagram illustrates an example of a voltage monitoring device 120 connected to more than one battery 110. However, this is exemplary and the voltage monitoring device 120 may be connected to more or fewer batteries than shown in FIG. 1.

The voltage monitoring device 120 comprises a voltage sensor 121 and a multiplexer 122. The voltage sensor 121 is configured to measure a voltage value of a battery. The multiplexer 122 is configured to sequentially electrically connect the voltage sensor 121 to the more than one battery 110, such that the voltage sensor 121 is connected to one battery at a given time. FIG. 1 shows five batteries 111, 112, 113, 114 and 115 connected to the voltage monitoring device. In this example, the multiplexer 122 is configured to sequentially electrically connect the voltage sensor 121 to the five batteries 111, 112, 113, 114 and 115 such that the voltage sensor 121 is connected to one battery at a given time. However, the more than one battery 110 may comprise any number of batteries.

The voltage monitoring device 120 is configured to connect to terminals of more than one battery 110. The voltage monitoring device 120 is further configured to sequentially electrically connect each battery 111, 112, 113, 114, 115 to the voltage sensor using the multiplexer 122 and measure a voltage value of the battery connected to the voltage sensor 121, wherein during the measurement the battery being measured is electrically connected only to the voltage monitoring device 120. For example, the battery is not electrically connected to load or to another battery. The voltage monitoring device 120 is further configured to record the voltage value of each battery against a battery identifier and a time stamp. The voltage monitoring device 120 is further configured to output the recorded voltage values (indicated by arrow 130). Outputting the recorded voltage values comprises displaying the recorded voltage values on a display. In an event that a recorded voltage value is below a threshold voltage, the voltage monitoring device 120 is further configured to provide a low voltage notification.

The multiplexer is configured to sequentially electrically connect the voltage sensor 121 to the more than one battery 110, such that the voltage sensor 121 is connected to one battery at a given time. A multiplexer comprises a device configured to select between several input signals and to forward the selected input signal to a single output. In certain embodiments, a shift register may be used with the multiplexer to sequentially electrically connect the voltage sensor 121 to the more than one battery 110. A shift register comprises a digital circuit comprising a cascade of latches or flip-flops. A latch or flip-flop comprises a circuit having two stable states that are able to store state information. One state may represent “one” and the other state may represent “zero”, such that a latch stores a single bit. The output of one latch is connected to the input of the next latch. The latches share a single clock signal, such that the data stored in the shift register shifts from one location to the next location. A shift register may therefore be used with the multiplexer to change the electrical connection to move between the batteries.

The voltage monitoring device 120 may be configured to repeat sequentially measuring a voltage value of each battery using a multiplexer at pre-determined time intervals. The voltage monitoring device 120 may sequentially electrically connect each battery 111, 112, 113, 114, 115 to the voltage sensor 122, measuring the voltage value of the battery connected to the voltage sensor 121. The voltage monitoring device may wait for a pre-determined time interval before again sequentially electrically connecting each battery 111, 112, 113, 114, 115 to the voltage sensor 122, measuring the voltage value of the battery connected to the voltage sensor 121. This may be repeated. For example, the voltage monitoring device 120 may be configured to repeat the measurements over a duration of storage of each battery.

In certain embodiments, the pre-determined time intervals may be constant. In certain embodiments, the pre-determined time intervals may vary. In certain embodiments, the pre-determined time intervals may be configurable by or changed by an operator.

Outputting the recorded voltage values may further comprise transmitting the recorded voltage values from the voltage monitoring device. Transmitting the recorded voltage values may occur wirelessly, or otherwise. The recorded voltage values may be transmitted to a controller or server. For example, the recorded voltage values may be transmitted to a server such that an operator at a location remote from the voltage monitoring device can view the recorded voltage values. The recorded voltage values may be transmitted to an office of an operator, or to the cloud. Transmitting the recorded voltage values may comprise transmitting the voltage values, the battery identifier for each voltage value and the time stamp for each voltage value.

The recorded voltage values may be stored, such that the recorded voltage values for a particular battery identifier at different time stamps may be compared. The recorded voltage values may be stored at the voltage monitoring device and/or at a remote storage device or server. The voltage monitoring values may be stored on the cloud.

The voltage monitoring device 120 is configured to display the recorded voltage values on a display. The voltage monitoring device 120 may be further configured to display the corresponding battery identifier for each recorded voltage value. In certain embodiments, providing the low voltage notification may comprise providing the notification on the display. The voltage monitoring device may comprise the display.

The low voltage notification may comprise any physical or digital notification.

In certain embodiments, providing the low voltage notification may comprise turning on an LED indicator. The LED indicator may be on the display, or elsewhere on the voltage monitoring device 120, or proximate to the voltage monitoring device. The LED indicator may be in a location remote from the voltage monitoring device, such as a central notification unit or in a location where an operator works. In certain embodiments, there may be one LED indicator per voltage monitoring device. In an event that any recorded voltage value for any of the batteries connected to the voltage monitoring device 120 is below a threshold voltage, the LED indicator for the voltage monitoring device 120 may be turned on. In certain embodiments, a further low voltage notification may indicate which of the more than one batteries connected to the voltage monitoring device 120 is below a threshold voltage. In certain embodiments, there may be one LED indicator per battery connected to the voltage monitoring device 120. The low voltage notification may comprise turning on the LED indicator for the battery having the low voltage.

In certain embodiments, the low voltage notification may comprise activating a buzzer. The buzzer may be on the voltage monitoring device 120, or proximate to the voltage monitoring device. The buzzer may be in a location remote from the voltage monitoring device, such as a central notification unit or in a location where an operator works. In certain embodiments, there may be buzzer per voltage monitoring device. In an event that any recorded voltage value for any of the batteries connected to the voltage monitoring device 120 is below a threshold voltage, the buzzer for the voltage monitoring device 120 may be activated. In certain embodiments, a further low voltage notification may indicate which of the more than one batteries connected to the voltage monitoring device 120 is below a threshold voltage. In certain embodiments, there may be one buzzer per battery connected to the voltage monitoring device 120. The low voltage notification may comprise activating the buzzer for the battery having the low voltage.

In certain embodiments, the low voltage notification may comprise sending a wireless message to a device or to a server. In certain embodiments, the low voltage notification may comprise providing a notification on a smartphone.

The low voltage notification may comprise one or more means of notification. The low voltage notification may indicate which of the more than one batteries connected to the voltage monitoring device has a voltage below the threshold voltage.

In certain embodiments, the voltage monitoring device comprises a notification means. In an event that a recorded voltage value is below a threshold voltage, the voltage monitoring device is configured to provide a low voltage notification using the notification means. The notification means of the voltage monitoring device may comprises one or more of a LED indicator and the display. In other embodiments, one or more of the LED indicator and the display may be remote from the voltage monitoring device.

The battery identifier may comprise an identifier unique to the battery. The battery identifier may, for example, comprise a serial number. The battery identifier may comprise an identifier indicative of the connection between the battery and the voltage monitoring device. The identifier indicative of the connection may be associated with the particular battery connected by the connection, such that the identifier indicative of the connection changes if the battery connected by the connection is swapped for a different battery. The identifier indicative of the connection may remain the same if the battery was swapped for a different battery, but the identifier indicative of the connection would allow the location of the battery to be identified based on the connection. The battery identifier may comprise an identifier indicative of a storage location of the battery. The identifier indicative of the storage location may remain the same if the battery was swapped for a different battery, but the identifier indicative of the storage location would allow the location of the battery to be identified. For example, the storage location may comprise a particular location on a particular shelf, storage level or storage unit, or the storage location may comprise some other coordinate indicating the specific location of the battery.

The battery identifier may be obtained by the voltage monitoring device. The battery identifier may be obtained by a sensor or by an operator. The battery identifier may be obtained via the connection between the battery and the voltage monitoring device. For example, the connection may have an identifier, such that the identifier of the connection is indicative of the connected battery. The connection may allow a battery identifier to be obtained from the battery. The battery identifier may be obtained once, when the battery is first physically connected to the voltage monitoring device. The battery identifier may be obtained using a visual tag such as a Radio Frequency Identification (RFID) tag, a quick response (QR) code or a bar code.

In an event that a recorded voltage value of a battery is below a threshold voltage, the voltage monitoring device may be further configured to charge the battery having the voltage value below a threshold voltage until the voltage value is at or above the threshold value. The voltage monitoring device may comprise a charger, or the charger may be separate to the voltage monitoring device. In an embodiment where the charger is separate to the voltage monitoring device, in an event that a recorded voltage value of a battery is below a threshold voltage, the voltage monitoring device instructs the charger to charge the battery having the voltage value below a threshold voltage until the voltage value is at or above the threshold value.

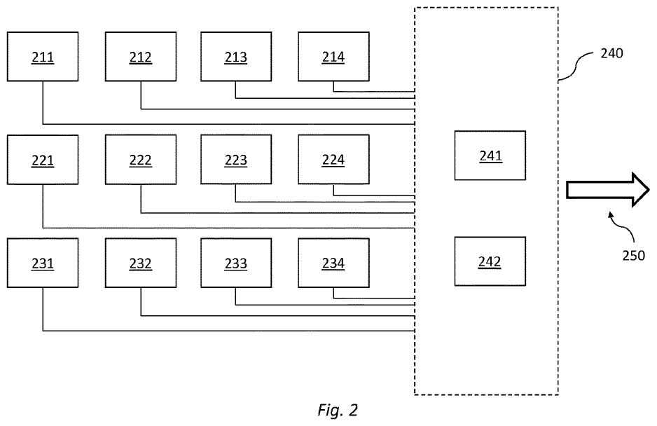

With reference to FIG. 2, in certain embodiments a rack may be provided, wherein the rack is configured to hold the voltage monitoring device 240 and the more than one battery. The voltage monitoring device comprises a voltage sensor 24 and a multiplexer 242. The voltage sensor 241 is configured to measure a voltage value of a battery. The multiplexer 242 is configured to sequentially electrically connect the voltage sensor 241 to the more than one battery, such that the voltage sensor 241 is connected to one battery at a given time. The voltage monitoring device 240 is configured to connect to terminals of more than one battery held by the rack. The voltage monitoring device 240 is further configured to sequentially electrically connect each battery to the voltage sensor using the multiplexer 242 and measure a voltage value of the battery connected to the voltage sensor 241, wherein during the measurement the battery being measured is electrically connected only to the voltage monitoring device 240. The voltage monitoring device 240 is further configured to record the voltage value of each battery against a battery identifier and a time stamp. The voltage monitoring device 240 is further configured to output the recorded voltage values (indicated by arrow 250). Outputting the recorded voltage values comprises displaying the recorded voltage values on a display. In an event that a recorded voltage value is below a threshold voltage, the voltage monitoring device 250 is further configured to provide a low voltage notification.

FIG. 2 shows three layers of batteries, each comprising four batteries such that the first layer comprises batteries 211, 212, 213 and 214, the second layer comprises batteries 221, 222, 223 and 224, and the third layer comprises batteries 231, 232, 233 and 234. The rack may comprise any number of layers of batteries. The rack may be configured to hold any number of batteries in a given layer. The rack may comprise one or more layers, wherein each layer is configured to hold one or more rows of batteries. The battery identifier may comprise a position on the rack at which the battery is held.

The voltage monitoring device in any of the preceding embodiments may further comprise a processor or controller. The processor may be configured to store the recorded voltage value of each battery and the corresponding battery identifier and time stamp. The voltage sensor may comprise any device configured to sense voltage. For example, the voltage sensor may comprise a voltage divider and an analogue to digital converter. The processor may comprise the analogue to digital converter.

The multiplexer is configured to sequentially connect the voltage sensor to the more than one battery, such that the voltage sensor is connected to one battery at a given time. This connection is electrical. The more than one battery may be physically connected to the voltage monitoring device at the same time (such that the voltage monitoring device is connected to the terminals of the batteries).

The voltage monitoring device is configured to be physically connected to more than one battery at a given time. In an event that a battery is removed, added or replaced, the voltage monitoring device may be configured to continue with the sequential measurement of the battery voltages at pre-determined time intervals. The battery identifiers may be changed to indicate the removal, addition or replacement of a battery. The sequence of measuring the batteries may change to accommodate removal or addition of a battery.

In certain embodiments, more than one voltage monitoring device may be provided, wherein each voltage monitoring device is according to an embodiment of this disclosure and is configured to connect to more than one battery. More than one rack may be provided, wherein each rack is configured to hold a voltage monitoring device and more than one battery.

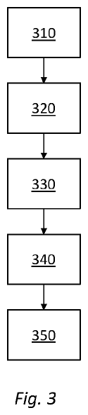

According to an embodiment of the disclosure, a method of monitoring voltages of more than one battery using a voltage monitoring device is provided. The voltage monitoring device comprises a voltage sensor configured to measure a voltage value of a battery; and a multiplexer configured to sequentially connect the voltage sensor to the more than one battery, such that the voltage sensor is connected to one battery at a given time. With reference to FIG. 3, the method comprises physically connecting the voltage monitoring device to terminals of more than one battery at step 310. At step 320, the method comprises sequentially electrically connecting each battery to the voltage sensor using the multiplexer and measuring a voltage value of the battery connected to the voltage sensor. During the measurement the battery being measured is electrically connected only to the voltage monitoring device. At step 330, the voltage value of each battery is recorded against a battery identifier and a time stamp. At step 340, the method comprises outputting the recorded voltage values, wherein outputting the recorded voltage values comprises displaying the recorded voltage values on a display. In an event that a recorded voltage value is below a threshold voltage, at step 350 a low voltage notification is provided.

Step 340 of outputting the recorded voltage values may occur sequentially for each battery being measured. Step 340 of outputting the recorded voltage values may occur after all the batteries have been measured.

In certain embodiments, steps 320 to 350 of the method may be repeated at pre-determined time intervals. The time intervals may be constant or may vary. The time intervals may be configurable by an operator.

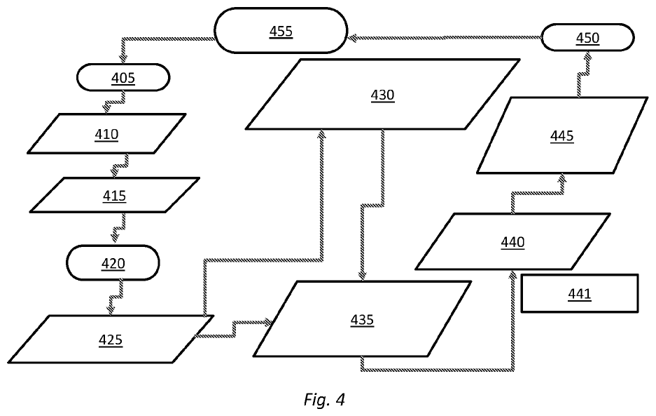

With reference to FIG. 4, a method of monitoring voltages of more than one battery using a voltage monitoring device according to an embodiment of the disclosure is illustrated. The method starts at 405. At step 410, more than one battery is placed on a rack. At step 415, the voltage monitoring device is physically connected to the terminals of the batteries. At step 420, the voltage monitoring device is activated. At step 425, the battery identifier of each battery is obtained. The battery identifier may be entered into the voltage monitoring device by an operator, or the voltage monitoring device may obtain the battery identifiers. At step 430, the voltage monitoring device electrically connects a battery to the voltage sensor using the multiplexer and measures a voltage value of the battery connected to the voltage sensor. At step 435, a processor received the battery identifier for the battery being measured, the measured voltage value and a time stamp. At step 440, the battery identifier for the battery being measured, the measured voltage value and a time stamp is displayed on a display of the voltage monitoring device. In an event that a recorded voltage value is below a threshold voltage, at step 441 a low voltage notification is provided. The low voltage notification may be shown on the display and/or may comprise turning on an LED indicator. At step 445, the battery identifier for the battery being measured, the measured voltage value and a time stamp are transmitted to a server or to the cloud. Steps 430 to 445 are repeated for each battery connected to the voltage monitoring device. In certain embodiments, steps 430 and 435 may be repeated for each battery connected to the voltage monitoring device, after which steps 440 to 445 may occur for all batteries. In certain embodiments, steps 430 and 445 may be repeated for each battery connected to the voltage monitoring device. The method may repeat steps 430 to 445 for all batteries at pre-determined time intervals. The method may stop at 450. One or more of the batteries may be swapped for a different battery at step 455, and the method may repeat.

A drop in voltage of a battery in storage may indicate a loss in battery health. For example, a drop in voltage of a battery in storage may indicate a lowering of the total capacity of the battery, or a change to the rate of charging or discharging of the battery. Recording the voltage values at different time stamps for a particular battery allows the battery health to be monitored over time. For example, in an event that a recorded voltage value drops below a threshold voltage for a particular battery and that battery is charged such that the voltage is above the threshold value, a subsequent drop in the voltage value for that battery may be indicative of an issue with the battery.

Recorded voltage values for a particular battery may be stored over time, such that historical recorded voltage values may be used to determine factors involved in whether a battery deployed from storage is healthy or whether a battery deployed from storage fails.

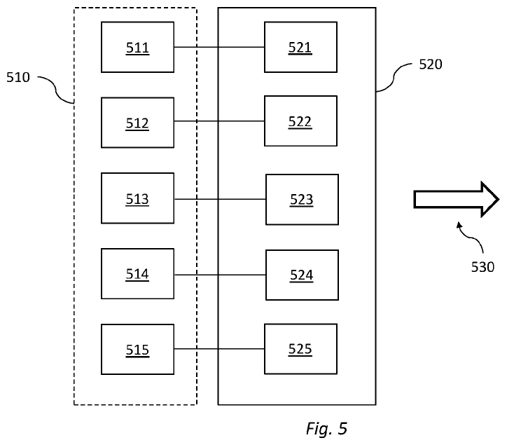

With reference to FIG. 5, according to another aspect of the disclosure, a voltage monitoring device is provided for monitoring voltages of more than one battery 511, 512, 513, 514 and 515. The voltage monitoring device comprises more than one voltage sensor 521, 522, 523, 524 and 525, wherein each voltage sensor 521, 522, 523, 524 and 525 is configured to measure a voltage value of a battery 511, 512, 513, 514 and 515. The voltage monitoring further comprises a housing 520 configured to contain the more than one voltage sensor 521, 522, 523, 524 and 525. FIG. 5 illustrates five voltage sensors each connected to a battery. However, there may be more or fewer voltage sensors. Each voltage sensor is configured to connect to one battery.

The voltage monitoring device is configured to connect a voltage sensor to terminals of each battery, such that each voltage sensor is connected to a battery. The voltage monitoring device is further configured to measure a voltage value of each battery connected to a voltage sensor, wherein during the measurement the battery being measured is electrically connected only to the corresponding voltage sensor. The voltage monitoring device is further configured to record the voltage value of each battery against a battery identifier and a time stamp. The voltage monitoring device is further configured to output the recorded voltage values (indicated by arrow 530), wherein outputting the recorded voltage values comprises displaying the recorded voltage values on a display. In an event that a recorded voltage value is below a threshold voltage, the voltage monitoring device is further configured to provide a low voltage notification.

The housing provides a convenient way to operate more than one voltage sensor. The outputs of the more than one voltage sensor (such as the recorded voltage values) may be consolidated for ease of use. For example, the outputs of each voltage sensor may be shown on a single display of the voltage monitoring device. In other embodiments, the outputs of each voltage sensor may be shown on different displays.

Outputting the recorded voltage values may further comprise transmitting the recorded voltage values from the voltage monitoring device. Transmitting the recorded voltage values may occur wirelessly, or otherwise. The recorded voltage values may be transmitted to a controller or server. For example, the recorded voltage values may be transmitted to a server such that an operator at a location remote from the voltage monitoring device can view the recorded voltage values. Transmitting the recorded voltage values may comprise transmitting the voltage values, the battery identifier for each voltage value and the time stamp for each voltage value.

The recorded voltage values may be stored, such that the recorded voltage values for a particular battery identifier at different time stamps may be compared. The recorded voltage values may be stored at the voltage monitoring device and/or at a remote storage device or server.

The voltage monitoring device is configured to display the recorded voltage values on a display. The voltage monitoring device may be further configured to display the corresponding battery identifier for each recorded voltage value. In certain embodiments, providing the low voltage notification may comprise providing the notification on the display.

In certain embodiments, providing the low voltage notification may comprise turning on an LED indicator. The LED indicator may be on the display, or elsewhere on the voltage monitoring device, or proximate to the voltage monitoring device. The LED indicator may be in a location remote from the voltage monitoring device, such as a central notification unit or in a location where an operator works. In certain embodiments, there may be one LED indicator per voltage monitoring device. In an event that any recorded voltage value for any of the batteries connected to the voltage monitoring device is below a threshold voltage, the LED indicator for the voltage monitoring device may be turned on. In certain embodiments, a further low voltage notification may indicate which of the more than one batteries connected to the voltage monitoring device is below a threshold voltage. In certain embodiments, there may be one LED indicator per battery connected to the voltage monitoring device. The low voltage notification may comprise turning on the LED indicator for the battery having the low voltage.

In certain embodiments, the low voltage notification may comprise activating a buzzer. The buzzer may be on the voltage monitoring device, or proximate to the voltage monitoring device. The buzzer may be in a location remote from the voltage monitoring device, such as a central notification unit or in a location where an operator works. In certain embodiments, there may be buzzer per voltage monitoring device. In an event that any recorded voltage value for any of the batteries connected to the voltage monitoring device 120 is below a threshold voltage, the buzzer for the voltage monitoring device may be activated. In certain embodiments, a further low voltage notification may indicate which of the more than one batteries connected to the voltage monitoring device is below a threshold voltage. In certain embodiments, there may be one buzzer per battery connected to the voltage monitoring device. The low voltage notification may comprise activating the buzzer for the battery having the low voltage.

In certain embodiments, the low voltage notification may comprise sending a wireless message to a device or to a server. In certain embodiments, the low voltage notification may comprise providing a notification on a smartphone.

The low voltage notification may comprise one or more means of notification. The low voltage notification may indicate which of the more than one batteries connected to the voltage monitoring device has a voltage below the threshold voltage.

In certain embodiments, the voltage monitoring device comprises a notification means. In an event that a recorded voltage value is below a threshold voltage, the voltage monitoring device is configured to provide a low voltage notification using the notification means. The notification means of the voltage monitoring device may comprises one or more of a LED indicator and the display. In other embodiments, one or more of the LED indicator and the display may be remote from the voltage monitoring device.

The battery identifier may comprise an identifier unique to the battery. The battery identifier may, for example, comprise a serial number. The battery identifier may comprise an identifier indicative of the voltage sensor connected to the battery. The identifier indicative of the voltage sensor may be associated with the particular battery connected to the voltage sensor, such that the identifier indicative of the sensor changes if the battery connected by the sensor is swapped for a different battery. The identifier indicative of the voltage sensor may remain the same if the battery was swapped for a different battery, but the identifier indicative of the voltage sensor would allow the location of the battery to be identified based on the voltage sensor. The battery identifier may comprise an identifier indicative of a storage location of the battery. The identifier indicative of the storage location may remain the same if the battery was swapped for a different battery, but the identifier indicative of the storage location would allow the location of the battery to be identified. For example, the storage location may comprise a particular location on a particular shelf, storage level or storage unit, or the storage location may comprise some other coordinate indicating the specific location of the battery.

The battery identifier may be obtained by the voltage monitoring device. The battery identifier may be obtained by a sensor or by an operator. The battery identifier may be obtained via the connection between the battery and the voltage sensor. For example, the connection may have an identifier, such that the identifier of the connection is indicative of the connected battery. The connection may allow a battery identifier to be obtained from the battery. The battery identifier may be obtained once, when the battery is first physically connected to the voltage monitoring device.

In an event that a recorded voltage value of a battery is below a threshold voltage, the voltage monitoring device may be further configured to charge the battery having the voltage value below a threshold voltage until the voltage value is at or above the threshold value. The voltage monitoring device may comprise a charger, or the charger may be separate to the voltage monitoring device. In an embodiment where the charger is separate to the voltage monitoring device, in an event that a recorded voltage value of a battery is below a threshold voltage, the voltage monitoring device instructs the charger to charge the battery having the voltage value below a threshold voltage until the voltage value is at or above the threshold value.

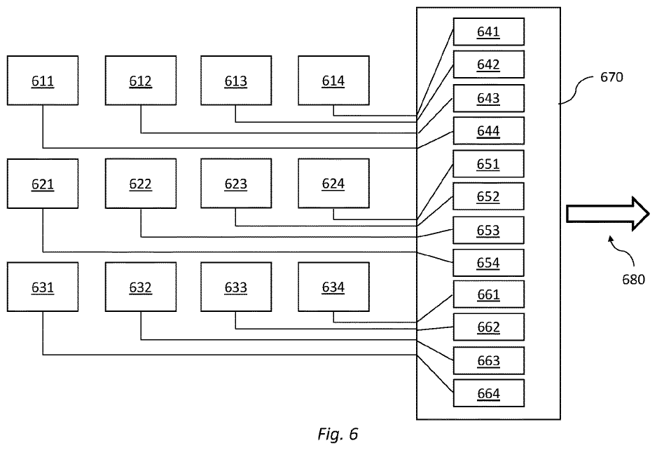

With reference to FIG. 6, in certain embodiments a rack may be provided, wherein the rack is configured to hold the housing 670 of the voltage monitoring device and the more than one battery 611, 612, 613, 614, 621, 622, 623, 624, 631, 632, 633, and 634. The voltage monitoring device comprises more than one voltage sensor 614, 642, 643, 644, 651, 652, 653, 654, 661, 662, 663, and 664. Each voltage sensor is configured to measure a voltage value of a battery. The voltage monitoring device is configured to measure a voltage value of each battery connected to a voltage sensor, wherein during the measurement the battery being measured is electrically connected only to the corresponding voltage sensor. The voltage monitoring device is further configured to record the voltage value of each battery against a battery identifier and a time stamp. The voltage monitoring device is further configured to output the recorded voltage values (indicated by arrow 680). Outputting the recorded voltage values comprises displaying the recorded voltage values on a display. In an event that a recorded voltage value is below a threshold voltage, the voltage monitoring device is further configured to provide a low voltage notification.

FIG. 6 shows three layers of batteries, each comprising four batteries such that the first layer comprises batteries 611, 612, 613 and 614, the second layer comprises batteries 621, 622, 623 and 624, and the third layer comprises batteries 631, 632, 633 and 634. The rack may comprise any number of layers of batteries. The rack may be configured to hold any number of batteries in a given layer. The rack may comprise one or more layers, wherein each layer is configured to hold one or more rows of batteries. The battery identifier may comprise a position on the rack at which the battery is held. The housing 670 is shown as containing twelve voltage sensors 614, 642, 643, 644, 651, 652, 653, 654, 661, 662, 663, and 664, each configured to connect to one of the batteries. The housing may contain more or fewer voltage sensors.

The battery identifier may comprise a position on the rack at which the battery is held.

The voltage monitoring device in any of the preceding embodiments may further comprise a processor or controller. The processor may be configured to store the recorded voltage value of each battery and the corresponding battery identifier and time stamp. The voltage sensor may comprise any device configured to sense voltage.

In an event that a recorded voltage value is below a threshold voltage, the voltage monitoring device may be further configured to charge the battery having the voltage value below a threshold voltage until the voltage value is at or above the threshold value.

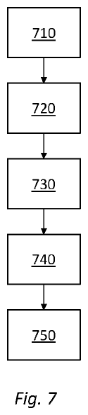

With reference to FIG. 7, a method of monitoring voltages of more than one battery using a voltage monitoring device according to an embodiment of the disclosure is illustrated. The voltage monitoring device comprises more than one voltage sensor, wherein each voltage sensor is configured to measure a voltage value of a battery. The voltage monitoring device further comprises a housing configured to contain the more than one voltage sensor.

The method comprises connecting a voltage sensor to terminals of each battery at step 710, such that each voltage sensor is connected to a battery. At step 720, the method comprises measuring a voltage value of each battery connected to a voltage sensor, wherein during the measurement the battery being measured is electrically connected only to the corresponding voltage sensor. At step 730, the voltage value of each battery is recorded against a battery identifier and a time stamp. At step 740, the method comprises outputting the recorded voltage values, wherein outputting the recorded voltage values comprises displaying the recorded voltage values on a display. In an event that a recorded voltage value is below a threshold voltage, at step 750 a low voltage notification is provided.

Steps 720 to 750 may be repeated at pre-determined time intervals.

### INDUSTRIAL APPLICABILITY

Batteries may be kept in storage, for example before being deployed in machines, vehicles or other battery powered devices. The performance of a deployed battery may be affected by the health of the battery during storage. The voltage monitoring device and method described herein may be used to detect a change to the voltage of a battery in storage, which may be indicative of other changes to the battery. A drop in voltage of a battery may, for example, be due to chemical reactions occurring in the battery that result in a loss of charge, and therefore a lower voltage.

Monitoring the voltages of batteries in storage may allow conditions of the battery to be improved. For example, a battery may be charged in an event that its voltage falls below a threshold. Monitoring the voltages of batteries in storage may allow an operator to choose a battery to deploy that is likely to be healthy. Monitoring the voltages of batteries in storage may allow an operator to identify batteries that may have degraded, in order to maintain or replace those batteries.

The recorded voltage values for a particular battery at different time stamps may be used to monitor health of the battery. For example, a battery may be charged in an event that its voltage is below a threshold. In an event that, after charging, the voltage of that particular battery subsequently falls below the threshold, it may be an indication of an issue with the battery.

The recorded voltage values for a particular battery at different time stamps may also be used to determine effects of voltage variation on future performance of the battery. For example, properties of batteries deployed after storage may be recorded against the recorded voltage values of that battery during storage. The resulting data may be used to determine effects of patterns or values of voltages of batteries in storage. The properties of the deployed battery may be indicative of battery health. For example, the properties may comprise one or more of a length of time for which a battery is deployed after storage without issue; a capacity of the battery over time; speed of charging or discharging the battery; or other property.

1. A voltage monitoring device for monitoring voltages of more than one battery, wherein the voltage monitoring device comprises:
more than one voltage sensor, wherein each voltage sensor is configured to measure a voltage value of a battery; and
a housing configured to contain the more than one voltage sensor;
wherein the voltage monitoring device is configured to:
connect a voltage sensor to terminals of each battery, such that each voltage sensor is connected to a battery;
measure a voltage value of each battery connected to a voltage sensor, wherein during the measurement the battery being measured is electrically connected only to the corresponding voltage sensor;
record the voltage value of each battery against a battery identifier and a time stamp;
output the recorded voltage values, wherein outputting the recorded voltage values comprises displaying the recorded voltage values on a display; and
in an event that a recorded voltage value is below a threshold voltage, provide a low voltage notification.

2. The voltage monitoring device of claim 1 wherein providing the low voltage notification comprises one or more of:
turning on an LED indicator;
providing a notification on a display;
activating a buzzer;
sending a wireless message to a device;
sending a wireless message to a server; and
providing a notification on a smartphone.

3. The voltage monitoring device of claim 1 wherein the voltage monitoring device further comprises a notification means, and wherein in an event that a recorded voltage value is below a threshold voltage, the voltage monitoring device is configured to provide a low voltage notification using the notification means.

4. The voltage monitoring device of claim 2 wherein the notification means of the voltage monitoring device comprises one or more of the LED indicator and the display.

5. The voltage monitoring device of claim 2 wherein one or more of the LED indicator and the display are remote from the voltage monitoring device.

6. The voltage monitoring device of claim 1 wherein the battery identifier is obtained by the voltage monitoring device.

7. The voltage monitoring device of claim 1, wherein in an event that a recorded voltage value is below a threshold voltage the voltage monitoring device is further configured to charge the battery having the voltage value below a threshold voltage until the voltage value is at or above the threshold value.

8. The voltage monitoring device of claim 7, wherein the voltage monitoring device comprises a charger configured to charge the battery.

9. The voltage monitoring device of claim 1 wherein the battery identifier comprises a unique identifier of the battery.

10. The voltage monitoring device of claim 1 further configured to display the voltage value of each battery and the corresponding battery identifier.

11. A rack configured to hold the voltage monitoring device according to claim 1, the rack further configured to hold the more than one battery.

12. The rack of claim 11 wherein the battery identifier comprises a position on the rack at which the battery is held.

13. A method of monitoring voltages of more than one battery using a voltage monitoring device comprising:
more than one voltage sensor, wherein each voltage sensor is configured to measure a voltage value of a battery; and
a housing configured to contain the more than one voltage sensor;
the method comprising:
a. connecting a voltage sensor to terminals of each battery, such that each voltage sensor is connected to a battery;
b. measuring a voltage value of each battery connected to a voltage sensor, wherein during the measurement the battery being measured is electrically connected only to the corresponding voltage sensor;
c. recording the voltage value of each battery against a battery identifier and a time stamp;
d. outputting the recorded voltage values, wherein outputting the recorded voltage values comprises displaying the recorded voltage values on a display; and
e. in an event that a recorded voltage value is below a threshold voltage, providing a low voltage notification.

14. The method of claim 13 wherein steps b) to e) are repeated at pre-determined time intervals.
